(19) United States
(12) Patent Application Publication
(10) Pub. No.: US 2026/0093866 A1
(43) Pub. Date: Apr. 2, 2026

(54) AUTOMATIC DESIGN DEVICE, AUTOMATIC DESIGN METHOD, AND PROGRAM

(71) Applicant: NEC Corporation, Tokyo (JP)

(72) Inventor: Takayuki KURODA, Tokyo (JP)

(73) Assignee: NEC Corporation, Tokyo (JP)

(21) Appl. No.: 19/335,275

(22) Filed: Sep. 22, 2025

(30) Foreign Application Priority Data
Oct. 1, 2024 (JP) 2024-172736

(51) Int. Cl. G06F 30/20

(52) U.S. Cl. CPC G06F 30/20

(57) ABSTRACT

An automatic design device includes a function for receiving an input of interest information that is a definition of a requirement to be satisfied by a system and an interest in a system, a function for generating a system configuration from the requirements, and a function for generating a design document for describing the system configuration in accordance with the interest information. The function for generating the design document extracts part of information from the requirement or the generated system configuration according to an extraction instruction included in the interest information to generate the design document.

This application is based upon and claims the benefit of priority from Japanese patent application No. 2024-172736, filed on Oct. 1, 2024, the disclosure of which is incorporated herein in its entirety by reference.

### TECHNICAL FIELD

The present disclosure relates to an automatic design device, an automatic design method, and a program of a system.

### BACKGROUND ART

For industrial development, it is necessary to actively utilize an information communication system (hereinafter, simply referred to as a system), but in general, a configuration of the system is complicated, and it is difficult to quickly provide and modify the system, which hinders the utilization.

For such a problem, JP 2021-135625 A discloses an automatic design technique for generating configuration information of a specific system based on requirements. According to the technology disclosed in JP 2021-135625 A, it is possible to generate completely embodied configuration information by repeating an operation of gradually implementing a configuration of an abstract system included in a given requirement. Each step of implementation includes generation and evaluation of a plurality of different configuration plans, and the most promising configuration plan is selected as the configuration plan to be implemented next.

In general, a system includes a wide variety of constituent elements such as a computer, a network, and an application, and a wide variety of requirements such as performance, availability, and security are considered in designing the system. In order to automate processing in consideration of such various information and conditions, standardization of information and simplification of processing are important. If implementation means for preparing different description formats and processing methods for each constituent element and requirement is adopted, the mechanism becomes extremely complicated, and it becomes difficult to introduce a new kind of constituent element and requirement.

Therefore, in the technology disclosed in JP 2021-135625 A and the like, information of each constituent element and requirement is abstracted and standardized. Specifically, the configuration information and the configuration plan of the system are expressed as single information by a specification in a graph format, and all kinds of constituent elements and relationships between constituent elements are expressed as nodes and edges. The requirements are also expressed based on a simple specification including inequalities and the like.

However, while expressing various pieces of information in an integrated and regular manner contributes to simplification of processing of automatic design, there is an aspect that prevents a user from grasping contents (for example, determination of a difference in kind for each constituent element, confirmation of whether each requirement is satisfied, and the like) of automatically generated system configuration information.

### SUMMARY

Therefore, an object of the present disclosure is to provide a technology for automatically generating, based on system requirements, information describing the contents of the system together with configuration information of the system satisfying the system requirements.

According to one aspect of the present disclosure, an automatic design device includes a means for receiving an input of interest information that is a definition of a requirement to be satisfied by a system and an interest in a system, a means for generating a system configuration from the requirements, and a means for generating a design document for describing the system configuration in accordance with the interest information. The means for generating the design document extracts part of information from the requirement or the generated system configuration according to an extraction instruction included in the interest information to generate the design document.

According to one aspect of the present disclosure, an automatic design method executed by a computer includes receiving an input of interest information that is a definition of a requirement to be satisfied by a system and an interest in a system, generating a system configuration from the requirements, and extracting part of information from the requirement or the generated system configuration in accordance with an extraction instruction included in the interest information to generate a design document for describing the system configuration.

According to one aspect of the present disclosure, a program for causing a computer to function as a means for receiving an input of interest information that is a definition of a requirement to be satisfied by a system and an interest in a system, a means for generating a system configuration from the requirements, and a means for extracting part of information from the requirement or the generated system configuration in accordance with an extraction instruction included in the interest information to generate a design document for describing the system configuration.

According to the present disclosure, it is possible to automatically generate, based on system requirements, configuration information of a system that satisfies the system requirements and information describing the contents of the system.

### BRIEF DESCRIPTION OF THE DRAWINGS

FIG. 1 is a block diagram illustrating a functional configuration of an automatic design device according to a first example embodiment;

FIG. 2A and FIG. 2B are first diagrams illustrating an example of configuration information according to the first example embodiment;

FIG. 2C is a second diagram illustrating an example of configuration information according to the first example embodiment;

FIG. 3A is a first diagram illustrating an example of type information of a component according to the first example embodiment;

FIG. 3B is a second diagram illustrating an example of the type information of the component according to the first example embodiment;

FIG. 3C is a third diagram illustrating an example of the type information of the component according to the first example embodiment;

FIG. 4 is a diagram illustrating an example of a design process of automatic design according to the first example embodiment;

FIG. 5 is a diagram illustrating an example of interest information according to the first example embodiment;

FIG. 6A and FIG. 6B are first diagrams illustrating an example of interest component information according to the first example embodiment;

FIG. 6C and FIG. 6D are second diagrams illustrating an example of the interest component information according to the first example embodiment;

FIG. 7 is a diagram illustrating an example of a result of document generation according to the first example embodiment;

FIG. 8 is a diagram illustrating an example of a selectivity according to the first example embodiment;

FIG. 9 is a flowchart illustrating an example of design and document generation operation according to the first example embodiment;

FIG. 10 is a block diagram illustrating an example of a functional configuration of an automatic design device according to a second example embodiment;

FIG. 11 is a flowchart illustrating an example of an operation of an automatic design device according to the second example embodiment; and

FIG. 12 is a diagram illustrating an example of a hardware configuration of the automatic design device according to each example embodiment.

### EXAMPLE EMBODIMENT

Hereinafter, an automatic design device of a system according to each example embodiment of the present disclosure will be described with reference to the drawings. In the drawings used in the following description, configurations of portions not related to the present disclosure may be omitted and not illustrated. In all the drawings, the same or related configurations are denoted by the same reference signs, and the common description may be omitted.

### First Example Embodiment (Configuration)

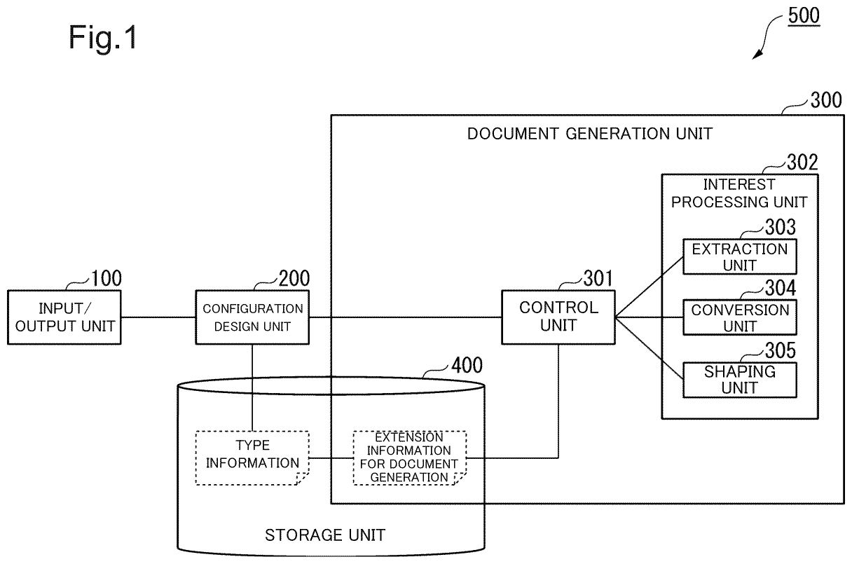

An automatic design device of a system according to a first example embodiment of the present disclosure will be described. FIG. 1 is a block diagram illustrating a functional configuration of an automatic design device according to the first example embodiment. As illustrated in FIG. 1, an automatic design device 500 includes an input/output unit 100, a configuration design unit 200, a document generation unit 300, and a storage unit 400. The document generation unit 300 includes a control unit 301 and an interest processing unit 302. The interest processing unit 302 includes an extraction unit 303, a conversion unit 304, and a shaping unit 305.

The input/output unit 100 has a function of inputting a system requirement and an interest information including an instruction regarding content desired to be described in a design document, a specific configuration obtained as a design result, and a function of outputting a design document or a document describing the content of the specific configuration, and is communicably connected to the configuration design unit 200.

The configuration design unit 200 has a function of designing a specific system configuration that satisfies given system requirements (the final system configuration obtained as a result of the design is referred to as a specific configuration). The configuration design unit 200 is communicably connected to the storage unit 400 in order to acquire type information of a component necessary for design. The configuration design unit 200 is communicably connected to the control unit 301 of the document generation unit 300 in order to request generation of a design document.

The document generation unit 300 has a function of generating, in response to a request from the configuration design unit 200, a design document including the explanation regarding the content of the specific configuration and a reason why the configuration indicated in the specific configuration has been selected from the given requirements.

The control unit 301 has a function of receiving a request for generating a design document including a specific configuration, a design history, and an interest information from the configuration design unit 200, generating the design document using the functions (the extraction unit 303, the conversion unit 304, and the shaping unit 305) of the interest processing unit 302, and returning the design document to the configuration design unit 200. Therefore, the control unit 301 is communicably connected to each of the extraction unit 303, the conversion unit 304, and the shaping unit 305. The control unit 301 has a function of acquiring the extension information for document generation recorded in the storage unit 400 and complementing the specific configuration, the design history, and the content of the interest information based on the information. The control unit 301 is communicably connected to the storage unit 400 in order to acquire the extension information for document generation.

The extraction unit 303 has a function of receiving the system requirement, the specific configuration, the design history, and the interest information from the control unit 301, generating post-extraction information obtained by extracting the element instructed by the interest information from the system requirement, the specific configuration, and the design history, and returning the post-extraction information to the control unit 301.

The conversion unit 304 has a function of receiving the post-extraction information and the interest information from the control unit 301, generating post-conversion information obtained by converting the post-extraction information based on the instruction described in the interest information, and returning the post-conversion information to the control unit 301.

The shaping unit 305 has a function of receiving the post-conversion information and the interest information from the control unit 301, generating post-shaping information obtained by shaping the post-conversion information based on the instruction described in the interest information, and returning the post-shaping information to the control unit 301.

The storage unit 400 has a function of readably recording the type information and the extension information for document generation.

Next, data used by the automatic design device 500 of the present example embodiment will be described. First, data used in an automatic design device without document generation will be described, and then data related to document generation will be sequentially described.

### (1) Data Used in Automatic Design Device Without Document Generation

Configuration information that is the most basic data structure in the automatic design device 500 will be described.

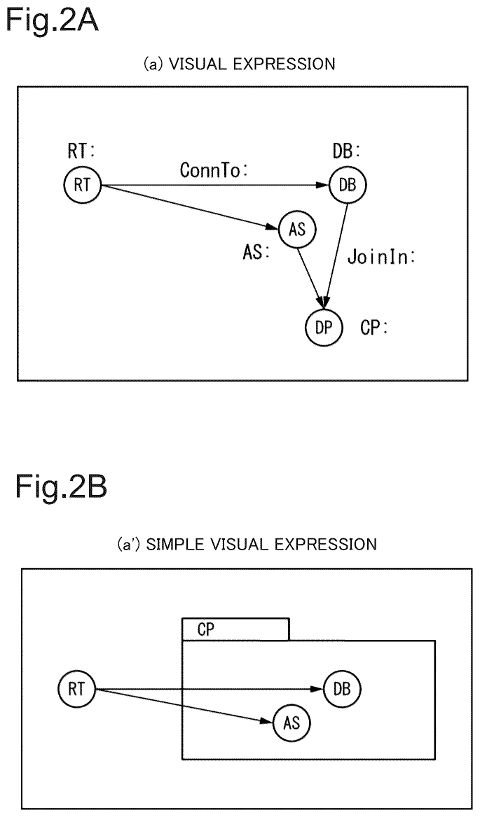

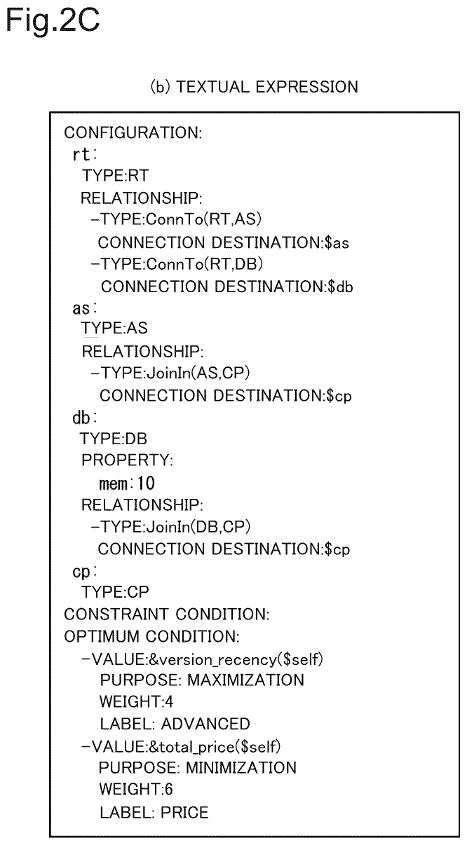

FIGS. 2A to 2C illustrate an example of the configuration information. FIGS. 2A and 2B illustrate both a visual expression ((a) of FIG. 2A and (a′) of FIG. 2B). FIG. 2C illustrates a textual expression ((b) of FIG. 2C) of the configuration information. For the visual expression, FIG. 2B illustrates an example of a simpler expression.

The configuration information is expressed by information in a graph form including nodes and edges. A node (circles of FIGS. 2A and 2B) expresses a part constituting a system, and is referred to as a component. An edge (arrows in FIGS. 2A and 2B) expresses a relationship between the components, and is referred to as a relationship. The components and the relationships are collectively referred to as constituent elements. Each constituent element has at least an id of the constituent element and type information indicating the kind of the constituent element. In addition, additional information such as a property may be included.

In the visual expression of FIG. 2A, a round symbol expresses a component (node), and an arrow connecting the circles expresses a relationship (edge). A label attached to a constituent element indicates a type and an id, a type name is indicated on the left side of a colon (“:”), and an id is indicated on the right side. Either or both of the type name and the id are omitted as appropriate. A label or an icon relevant to the kind of the type is appropriately displayed in the circle of the component. In the example of the configuration information illustrated in FIGS. 2A to 2C, RT expresses a router, and AS and DB express software called an application server and a database.

RT is connected in a ConnTo relationship with AS and DB, which expresses a relationship that RT and AS, and RT and DB are connected in a communicable manner. The CP expresses a cloud platform, and AS and DB are connected in a JoinIn relationship with CP, which expresses a relationship that AS and DB are constructed on CP and operate.

In the simple visual expression illustrated in FIG. 2B, CP is expressed by a frame, and a JoinIn relationship of AS and DB with respect to CP is expressed in correspondence with arrangement of AS and DB inside the frame of CP. Since some relationships, such as JoinIn, may be connected between one component and many other components, at that time, visibility is significantly reduced in a normal visual expression as illustrated in FIG. 2A, a simplified visual expression as illustrated in FIG. 2B is appropriately used herein.

In the textual expression of FIG. 2C, the information is described in a YAML format. The configuration information can have a “configuration”, a “constraint condition”, and an “optimum condition”.

In the “configuration”, ids of components included therein are listed, and information of each component is described as an attribute of each id. The “type” is a type of each component. The “relationship” is a relationship from each component to another component. The relationship is expressed by an array, and “type” and “connection destination” are described as attributes of each relationship. The relationship type includes a set of a basic type, which is its own type of relationship, and a both-end type, which is the type of components at both ends. For example, when described as JoinIn(AS, CP), JoinIn is the basic type, and AS and CP are the both-end types. In the “connection destination”, an id of a component to which a relationship is established is specified in a reference format. The reference format is a character string in which “$” is added to the beginning of the character string of id, and indicates that another element is referred to.

In the “constraint condition”, a condition to be satisfied by the configuration is described. Finding the configuration information satisfying the constraint condition is one of termination conditions of the automatic design processing. An example of the constraint condition will be described later.

The “optimum condition” is a criterion for comparing goodness between a plurality of different pieces of configuration information, and four items of a value, a purpose, a weight, and a label are described. The value is a value to be optimized, and an equation or a function for calculating the value to be optimized from the configuration information of the implemented result is specified.

It is assumed that the function takes an expression in which “&” is added to the beginning of a character string expressing a function name, and arguments are described with parentheses in the subsequent stage.

The purpose expresses a desired state for a target value, and maximization, minimization, and the like are specified. The weight is a value indicating a degree to which a target optimum condition is emphasized in a case where a plurality of optimum conditions is designated.

The configuration information illustrated in FIG. 2C includes four components “rt”, “as”, “db”, and “cp”. Among them, when “rt” is adopted as an example, it is an RT type, and as the relationship, ConnTo(RT, AS) type relationship with “as” as the connection destination and ConnTo(RT, DB) type relationship with “db” as the connection destination are held. As the optimum condition, it is assumed that the total price is minimized while maximizing the freshness of the components used, and the weight of the former is set to 4 and the weight of the latter is set to 6.

The system requirement relevant to the input information of the automatic design device 500, the configuration plan in the middle of design relevant to the intermediate generation information, and the specific configuration relevant to the output information are all expressed by the configuration information.

Next, the type information of each constituent element will be described. The type information of the constituent element has attributes of a type name, an inheritance source, a concreteness flag, a property, and an expected configuration. A type of each constituent element can be inherited by designating a name of a type of another constituent element as an inheritance source.

The type of the constituent element can be extended or overwritten by adding only a portion different from the type information of the inheritance source after inheriting the type of the other constituent element to inherit the information of the inheritance source.

The inherited type is called a derivative type, an extended type, or the like, and is regarded as a kind of the type of the inheritance source.

The concreteness flag is a flag indicating whether the type is a specific type.

The property is information indicating an attribute value that can be held by the type.

The expected configuration is a peripheral configuration to be satisfied by a component having a certain type in order to establish specific configuration information. For example, the APS type component needs to be connected to the OS type component with a HostedOn(APS, OS) type relationship. Such a condition that a certain component requires in the peripheral configuration is designated as the expected configuration. One constituent element can include a plurality of expected configurations, but an example of type information including two or more expected configurations is not used in the present specification.

As will be described later, the concreteness flag and the expected configuration are used as a termination condition of the automatic design search processing. That is, for all the constituent elements included in a certain configuration, a condition that the type is a specific type and the expected configuration is satisfied is a part of the termination condition of the automatic design search processing.

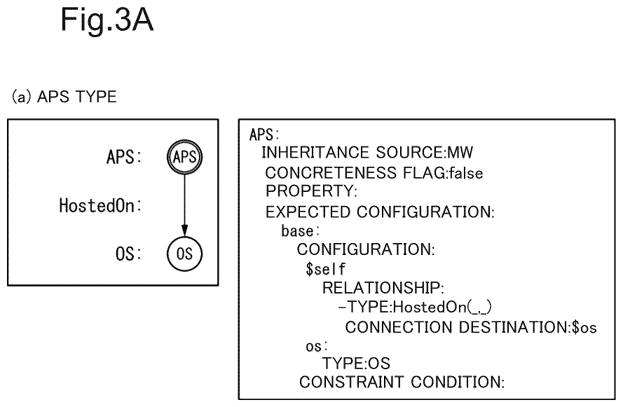

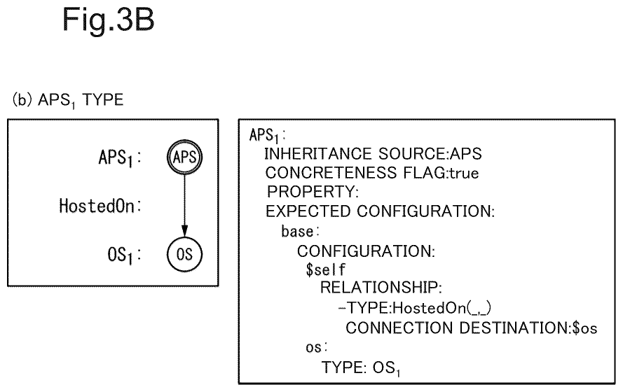

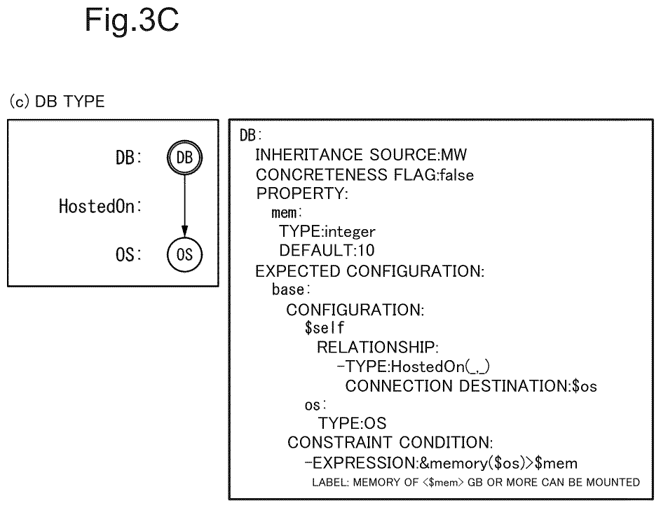

FIGS. 3A to 3C illustrate a comparison between an example of a visual expression and a textual expression of component type information. The visual expressions on the left side of FIGS. 3A to 3C express one of the expected configurations. The expected configuration is expressed as a partial configuration including the component type itself for obtaining the expected configuration. In the visual expression of the type information of the constituent elements in the present specification, it is assumed that the element itself is expressed by a double line constituent element. As described above, one constituent element can include a plurality of expected configurations, but an example of type information including two or more expected configurations is not used in the present specification, and thus the visual expression of the type information is simply expressed as one expected configuration. The both-end types of the relationship type are appropriately omitted and expressed.

In the textual expressions on the right side of FIGS. 3A to 3C, “inheritance source”, “concreteness flag”, “property”, and “expected configuration” are described. Since one constituent element can include a plurality of expected configurations, it is assumed that a name of the expected configuration is designated, and information of the expected configuration is described as an attribute thereof. In the example textual expression of FIGS. 3A to 3C, “base” is the name of the expected configuration. The content of the expected configuration is the configuration information itself. However, the id of the defined type itself is described as $self which is a special reference name.

In a case where the both-end type of the relationship type is omitted by “_”, the types of the constituent element at both ends specified in the definition information are used. For example, in the textual expression related to the APS type in FIG. 3A, HostedOn(_,_) which is the first relationship held by $self is described such that the connection source is $self and the connection destination is $os. Since it is described that $self is the APS type itself and the type of $os is OS, the formal type name of this relationship shall be interpreted as HostedOn(APS, OS).

FIG. 3B illustrates a description of APS₁ type, which is a derivative type that inherits the APS type. The APS₁ type basically takes over APS type information, but since some pieces of information are different, different parts are described in an overwriting manner. The APS type is designated as an inheritance source. Since the APS type is an abstract type, whereas the APS₁ type is a specific type, the concreteness flag is overwritten with true. The APS type specifies that the APS type is connected to an arbitrary OS type constituent element in a HostedOn relationship, but the operation is not correctly performed unless the OS₁ type is used in the APS₁ type, and thus the type name is overwritten with the OS₁ type.

FIG. 3C illustrates a description about a DB type. The DB type description is similar to the APS type description, but is different here in that a constraint condition is specified. The constraint condition has two items of an expression and a label. Expressions shall describe inequalities to be satisfied. Here, the portion of “&memory($os)” expresses the capacity of the memory held by the target operating system (OS) in which the DB (database) is hosted, and indicates that it is larger than the amount indicated by “$mem”. “$mem” is a variable described in a DB type property, and “10” (“mem:10” of the property of $db in the configuration information of FIG. 2C) is given in the example illustrated in FIG. 2C. As will be described later, the label is a template of an explanatory sentence used in document generation. A variable portion is expressed by parentheses, and for example, by applying a value “10” to a portion of “$mem”, an explanatory sentence of a constraint condition such as “a memory of 10 GB or more can be mounted” can be generated. If the property $db in the configuration information of FIG. 2C has a memory capacity setting, this value is referred to, and if this setting does not exist, the default value (“Default: 10” in the type definition in FIG. 3C) is referred to. Although detailed description is omitted in the present specification, substantially similar type information is also defined for the relationship.

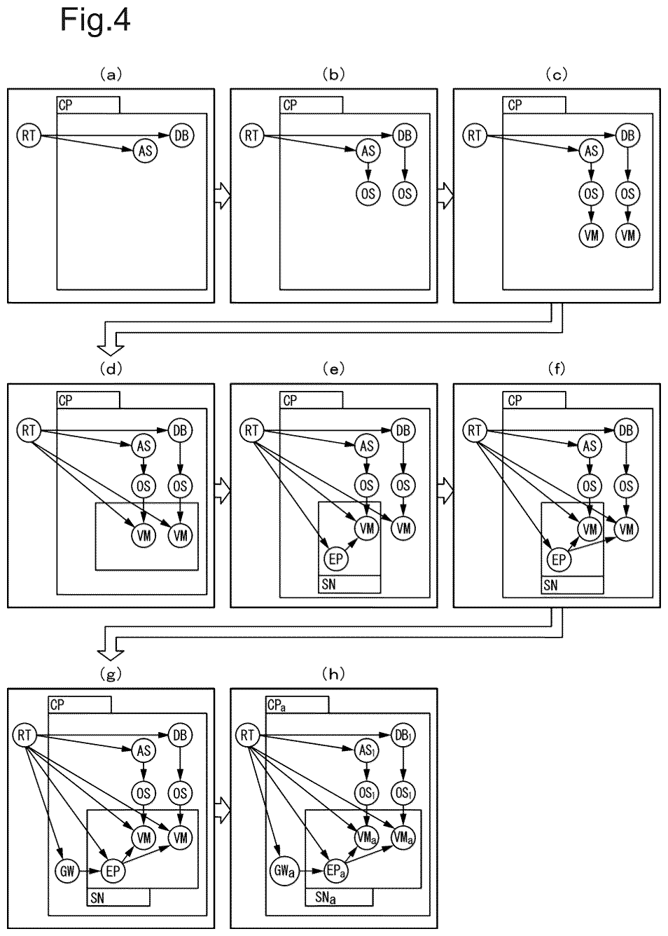

FIG. 4 illustrates an example of a design process by the automatic design device of the present invention. A series of pieces of configuration information in (a) to (h) of FIG. 4 shows a state starting from a system requirement until implementing a final specific configuration which is completely specific configuration information. That is, (a) of FIG. 4 is an example of a system requirement, and expresses a request of a user to construct AS and DB on a certain CP so that the constructed AS and DB can be connected from an external RT. The configuration plan of (b) is obtained by applying base which is each type of expected configuration to the AS type of component and the DB type of component of (a).

Similarly, the configuration plan of (c) is obtained by applying the OS type of expected configuration to the OS type of component of (b). By repeating the same processing, (d), (e), (f), and (g) are obtained. At stage of (g), all expected configurations have been complemented, but the type of each constituent element is not a specific type, so the system design is not yet completed. Therefore, a step of replacing the non-specific type with any extended type that inherits the non-specific type proceeds. By repeating the step of implementing such a type, (h) is generated as an example.

In the steps from (a) to (b) of FIG. 4, “base” that is the expected configuration is applied to the DB type of component. At this time, the constraint condition described in “base” that is the DB type of expected configuration illustrated in FIG. 3C is also reflected as a part of the constraint condition to be satisfied by the configuration information.

In FIG. 4, the design process is illustrated as a process of one way for convenience of description, but actually, the process branches into a large number of pieces of configuration information because the expected configuration may have a plurality of candidates, there may be a plurality of candidates for an extended type that inherits a certain abstract type, and which constituent element is implemented can be arbitrarily selected. The automatic design device 500 derives configuration information that satisfies the optimum condition at the highest possible level among the specific configuration information suitable for the three points of that the types of all the constituent elements are specific, that the expected configurations of all the constituent elements are complemented, and that the constraint conditions of all the constituent elements are satisfied while following such a bifurcatable process in an exploratory manner.

In addition, for convenience of description, a plurality of steps of implementation are expressed by one arrow in the example of FIG. 4. For example, the transition from (a) to (b) of FIG. 4 includes two steps of complementing an AS type of element with an OS type of element and complementing a DB type of element with an OS type of element. In the example of FIG. 4, the case where the complement of the expected configuration is executed first in the steps (a) to (g) and then the type is implemented has been described. However, the complement of the expected configuration and the implementation of the type may be executed in an arbitrary order. In the present specification, the above-described information regarding the process of implementation including branching in the middle is referred to as a design history.

CP and SN are displayed in frames in (a) to (h) of FIG. 4 for easy understanding of the description, but actual information has a complicated structure in which each element in the frame and the element displayed in the frame are connected by a relationship, and it is difficult to understand the content in many cases. Therefore, in the present example embodiment, a design document/document including the reason why the configuration indicated in the specific configuration is selected from the contents of the specific configuration and the system requirements is generated.

### (2) Data for Document Generation

The data used in the conventional automatic design device without document generation has been described above. Hereinafter, data for document generation in the present invention will be described.

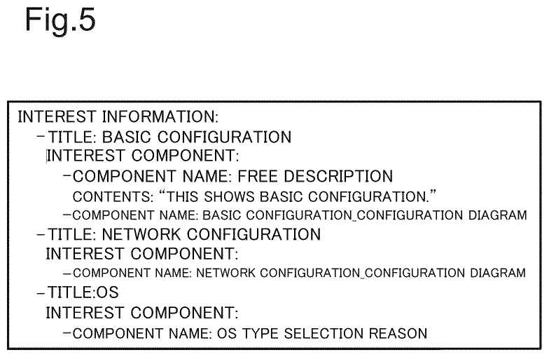

FIG. 5 illustrates an example of the interest information. The content of the interest information is an instruction related to the content of a document desired to be generated together with the design result of the system, and is described as a list of a plurality of interests. Each interest includes a title and a list of interest components. The title is the name of the interest, and may be used as the title of the sentence when the document is generated. The interest component is a more specific instruction regarding the content of the document, and includes a component name, an attribute according to a component kind, and the like.

In the example of FIG. 5, the interest information includes three interests. The title of the first interest is “basic configuration” and contains two interest components. The component name of a first interest component is “free description”, and the description of “basic configuration is indicated” is given as the content. The component name of a second interest component is “basic configuration_configuration diagram”. The title of the second interest is “network configuration” and contains one interest component. The component name of the interest component is “network configuration_configuration diagram”. The title of the third interest is “OS” and includes one interest component. The component name of the interest component is “OS type selection reason”.

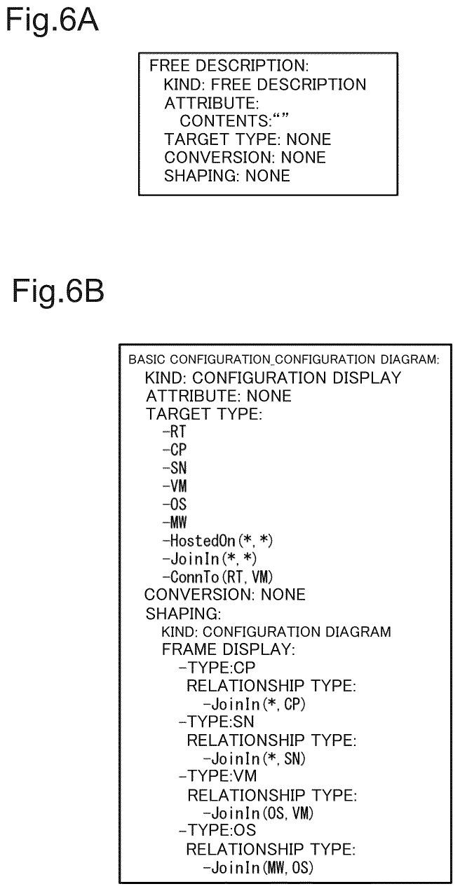

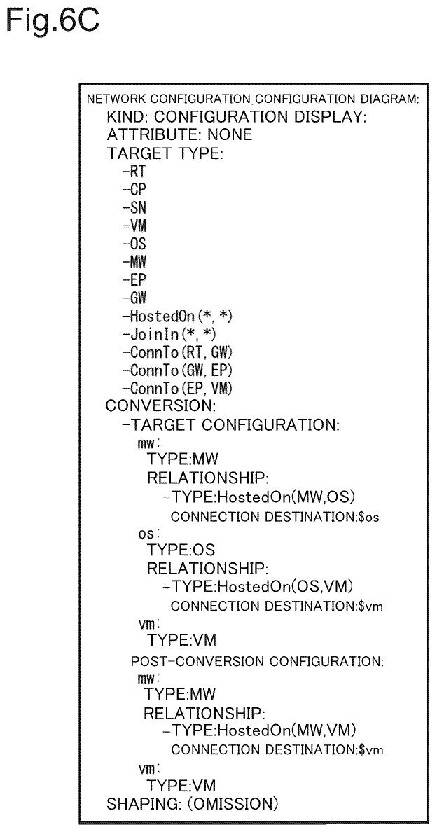

FIGS. 6A to 6D illustrate an example of the interest component information. The interest component information is information in which instructions related to specific contents of a document to be generated are collected in a reusable manner. FIG. 6A illustrates the interest component information of “component name: free description”. FIG. 6B illustrates the interest component information of “component name: basic configuration_configuration diagram”. FIG. 6C illustrates the interest component information of “component name: network configuration_configuration diagram”. FIG. 6D illustrates the interest component information of “component name: OS type selection reason”. These are all referred to from the interest information illustrated in FIG. 5. For example, the interest component information may be registered in the storage unit 400 in advance.

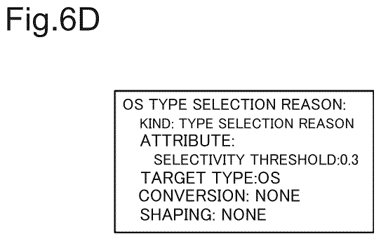

FIG. 7 illustrates an example of a result of document generation. As an aspect of the document generated by the document generation unit 300, it is assumed that the generated document is a document in a format in which each interest matter included in the interest information is set as a chapter and the chapters are collected. The example document illustrated in FIG. 7 includes three chapters, each relevant to the three interest matters illustrated in FIG. 5 (basic configuration, network configuration, OS). The title of the first chapter of the document of FIG. 7 is “Basic Configuration”, which is derived from the title of the first interest in the interest information. In the head of the first chapter of the document, it is described that “Basic configuration is indicated”, which is derived from the fact that a free description is given as the first interest component in the first interest in the interest information of FIG. 5, and a description of “Basic configuration is indicated” is given in the content. That is, “free description”, which is a kind of the interest component, has a function of developing a sentence given as “content” into a document as it is. The first chapter of the document of FIG. 7 subsequently shows a configuration diagram, which derives from the fact that “basic configuration_configuration diagram” is given as the second interest component in the first interest of the interest information.

In the interest component of “basic configuration_configuration diagram” illustrated in FIG. 6B, “configuration display” is designated as a kind. The “configuration display”, which is a type of interest component, has a function of displaying a system configuration in a document. The interest component in the “configuration display” receives three instruction information: “target type”, “conversion” and “shaping”. The “target type” is a list of types of constituent elements to be displayed in the system configuration among the design results. The extraction unit 303 extracts a display target based on the “target type”. The “conversion” is a correction content in a case where correction is desired in displaying the content of the system configuration. The conversion unit 304 corrects and converts the display content based on the “conversion”.

“Shaping” is an instruction regarding a final expression method. As a final expression method, various forms such as a figure, a table, and a sentence can be considered. Therefore, a specific means is separately defined, and here, a form is adopted in which a means prepared in advance is designated as “kind” and used.

Therefore, the attribute value for each designated “kind” is described, and here, a description regarding the attribute “frame display” required in the “configuration diagram” is given. The shaping unit 305 generates a document by the expression method based on this “shaping”.

That is, the configuration diagram illustrated in the first chapter of FIG. 7 is a result of conversion of the configuration information in (h) of FIG. 4 according to the content of the interest component in “basic configuration_configuration diagram” in FIG. 6B. Components relevant to derivative types such as GW and EP not described in the target type in FIG. 6B are omitted. The “deformation” is not particularly implemented. The final content is expressed as a configuration diagram, and according to the instruction content of “frame display”, elements of CP, SN, VM, and OS are expressed by the appearance of a frame, and constituent elements indicated as “relationship type” are displayed in the frame.

The title of the second chapter of the document illustrated in FIG. 7 is “network configuration”, which is derived from the title of the second interest in the interest information. The configuration diagram shown in the second chapter of FIG. 7 is derived from “network configuration_configuration diagram”, which is the interest component in the second interest in the interest information of FIG. 5. The “network configuration_configuration diagram” is illustrated in FIG. 6C, the content of which is similar to FIG. 6B described above, but the difference lies in that the content of the target type and an element of conversion are included. Since the content of the target type is different, the configuration diagram of the second chapter also includes components relevant to derivative types of GW and EP. In the item of conversion in FIG. 6C, the target configuration and the post-conversion configuration are illustrated, that is, it is instructed to convert a portion matching the target configuration into the post-conversion configuration. Here, as the target configuration, a configuration in which an MW-type element is connected to an OS type of element in a HostedOn type relationship and the OS type of element is connected to a VM-type element in a HostedOn type relationship is indicated, and as the post-conversion configuration, a configuration in which the MW-type element is directly connected to the VM-type element in a HostedOn type relationship is indicated. As a result of conversion according to such a conversion instruction, the OS is omitted in the diagram of the second chapter of FIG. 7, and the AS1-type element and the DB1-type element are directly included in the VM1-type element.

The title of the third chapter of the document shown in FIG. 7 is “OS”, which is derived from the title of the third interest in the interest information of FIG. 5. In the third section of FIG. 7, a sentence describing the selection result of the OS type and the selection reason is illustrated. This explanatory sentence is derived from “OS type selection reason” which is an interest component in the third interest in the interest information in FIG. 5. In “OS type selection reason” illustrated in FIG. 6D, “type selection reason” is designated as a kind, a selectivity threshold is designated as “0.3” as an attribute, and “OS” is designated as a target type.

Here, the “type selection reason” is an interest component having a function of generating a sentence that explains the selection reason regarding the implementation of the latter type among “complement of expected configuration” and “implementation of type” that are implementation steps of two kinds of main configuration information in the automatic design device 500. As described above, when the configuration information to be implemented includes a constituent element having a type in which the value of the concreteness flag is false, the automatic design device 500 implements the configuration information by replacing the constituent element with a derivative type that inherits the type. At this time, in a case where there are a plurality of derivative types that inherit the target type, a promising derivative is selected and applied from among them. The interest component of the “type selection reason” generates an explanatory sentence based on the information of the design history regarding the selection of the type designated by the target type. Specifically, a list of types existing as other options, the type selected as a result, and a description regarding the constraint condition and the optimum condition that affected the selection are generated.

The other options can be obtained by extracting branch information of points where the type of the target type is replaced with the derivative type in the design history, or by extracting a list of types having the target type as an inheritance source from a list of type information of the configuration information.

As for the constraint conditions, descriptions for all the considered constraint conditions may be generated, but only those that have affected the selection may be extracted and generated. In the extraction of the constraint condition that has affected the selection, for example, the configuration information of the branch of the point where the type of the target type is replaced with the derivative type in the design history may be extracted, the success or failure of the establishment of the constraint condition in each configuration information may be confirmed, and the constraint condition in which the number of candidates is most narrowed may be extracted. For example, it is assumed that there are three pieces of configuration information S1, S2, and S3 as the configuration information immediately after the target type is replaced with the derivative type and the configuration information of the branch, and three constraint conditions C1, C2, and C3 are applied to these pieces of configuration information and evaluated. Among them, it is assumed that the condition C1 is satisfied in all the pieces of configuration information S1 to S3, C2 is satisfied only in S1 and S2, and C3 is satisfied only in S1. At this time, since C3 is a condition in which the number of candidates is narrowed down to the smallest, C3 may be set as a constraint condition affecting the selection. If C3 is satisfied only in S1 and S3, the candidates of C2 and C3 are narrowed down to the same extent, and the final number of candidates is narrowed down by combining the two constraint conditions. Therefore, these two constraint conditions may be extracted as the constraint conditions affecting the selection.

As for the optimum conditions, descriptions for all the considered optimum conditions may be generated, but only those having an influence on selection may be extracted and generated. For the extraction of the optimum condition that has affected the selection, for example, the configuration information of the branch of the point where the type of the target type is replaced with the derivative type in the design history may be extracted, the examination result of the optimum condition in each configuration information may be confirmed, and the optimum condition that has contributed most to the selected candidate may be extracted as a result. For example, it is assumed that there are three pieces of configuration information S1, S2, and S3 as the configuration information immediately after the target type is replaced with the derivative type and the configuration information of the branch, and three optimum conditions P1, P2, and P3 are applied to these pieces of configuration information and evaluated. Among them, if the value of P1 is 10 in any of S1 to S3 in the comparison of the evaluation values after being multiplied by the weight, it is not determined that this particularly affects the selection. If P2 is 10 in S1, 8 in S2, and 8 in S3, it can be determined that it has contributed to dominating S1 over other candidates. If P3 is 10 in S1, 2 in S2, and 1 in S3, it can be determined that P3 also contributes to the superiority of S1 over other candidates. However, since it can be determined that the degree of contribution is higher in P3 than in P2, P3 can be determined as the optimum condition affecting the selection. Alternatively, the standard deviation regarding the value of the evaluation value of each optimum condition in another candidate is calculated, and the optimum condition having the largest value and the optimum condition having the value of the standard deviation within a certain threshold may be listed as the optimum condition affecting the selection.

When the sentence of the selection reason is generated based on the list of types existing as other options, the type selected as a result, and the extraction information regarding the constraint condition and the optimum condition that have affected the selection described above, a template may be held in the interest component of the “type selection reason” and the extraction information may be applied to the template to generate the sentence of the selection reason.

For example, a template such as “There is <option type> as the kind of <target type>, and <selected type> has been selected in the present case. The reason is that <target type> needs <list of constraint conditions> in the present case, and <selected type> among them has particularly an excellent <list of optimum conditions>”. The value of each variable is generated from the extraction information by the interest component of the “type selection reason”. At this time, the labels illustrated in FIGS. 2A to 2C, and 3A to 3C may be used.

For the value of <option type>, a character string in which possible options are connected by “and” may be generated and used. In a case where the number of options is equal to or more than a specific threshold, “or the like” may be added to the end after omission.

Here, a point that a type selection is performed in multiple stages in the automatic design device 500 will be supplemented. For example, it is assumed that there is a type called a DB type, and two types called an RDB type and a NOSQL type are provided as derivative types thereof. At this time, it is assumed that the value of the concreteness flag of the DB type is false, but the value of the concreteness flag may also be false for the RDB type and the NOSQL type. These may be inherited by other derivative types, and a type in which the value of the concreteness flag is true may be defined at the end of the inheritance relationship. In a case where there is such a multi-stage inheritance relationship, in a case where the selection reason of the type having the DB type as the target type is generated, basically, a plurality of selection reasons as described above may be listed. For example, when the RDB type is selected as the derivative of the DB type and the RDB1 type is selected as the derivative of the RDB type, the selection reason of the RDB type and the selection reason of the RDB1 type may be listed.

However, in general, the type derivative relationship often extends over a large number of stages, and if the reason for all the choices is stated, there is a concern that the explanatory sentence may be excessively redundant. In order to avoid this, a method of indicating the reason only for the determination of selection that needs to be noted is conceivable. For example, in a case where the standard selection is followed, the description of the reason may be omitted, and the reason may be described only in a case where an option that is not frequently selected is determined.

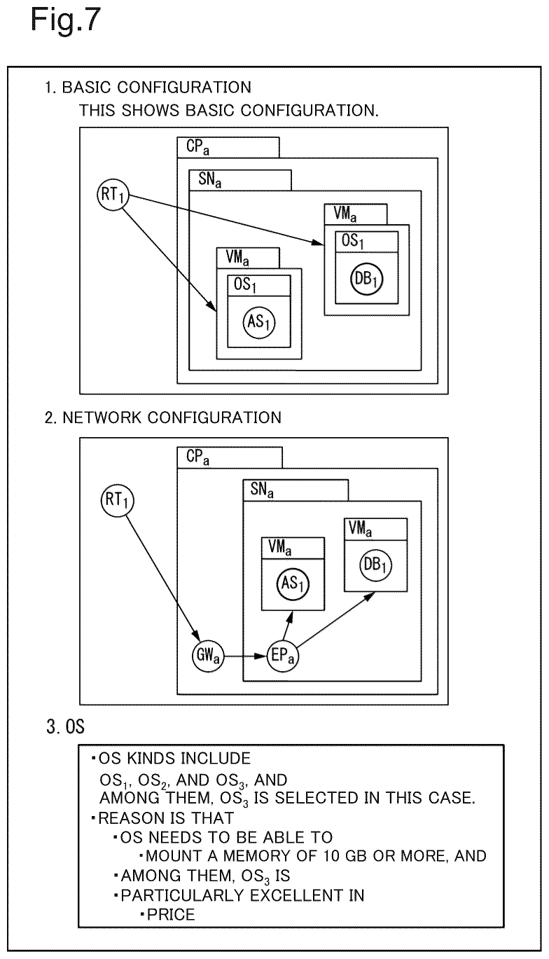

FIG. 8 is an example of information regarding the selectivity of each selection.

The information on the selectivity may be recorded in the storage unit 400 as the extension information for document generation and given to the extraction unit 303, the conversion unit 304, and the shaping unit 305 via the control unit 301.

In the example of FIG. 8, in the selection of the derivative type of the OS type, “OS1”, “OS2”, “OS3”, and “others” are assumed, and “0.5”, “0.3”, “0.1”, and “0.1” are given as the selectivities. Among them, for example, the reason may be generated only when selection below a specified selectivity threshold is made. For example, in the interest component shown in FIG. 6D, “0.3” is given as the selection threshold, and thus, when “OS1” or “OS2” is selected, generation of the reason may be omitted.

In the example of the present specification, the method of defining the information of the selectivity in advance has been exemplified. However, a plurality of options in each determination of the design process by the configuration design unit 200 and options selected in the determination may be recorded in the storage unit 400 as an execution history of automatic design, and the configuration design unit 200 may automatically calculate the information of the selectivity by taking statistics from the accumulated selection history.

In the present specification, three kinds of “free description”, “configuration display”, and “type selection reason” are exemplified as types of interest components, but other component types may be defined and extended. Only the “configuration diagram” has been exemplified as the kind of the shaping means, but the type of other shaping means such as a shaping means for generating a different kind of “configuration diagram” or a shaping means for displaying a “table” may be defined and extended. In the above example, the information included in the design document is extracted from the specific configuration and design history, but may be extracted from the system requirements.

### (Operation)

Next, the operation of the automatic design device 500 will be described.

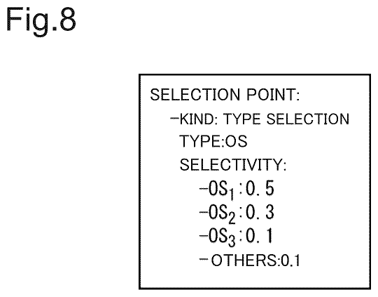

FIG. 9 is a flowchart illustrating an example of design and document generation operation according to the example embodiment.

First, an input of the system requirement and the interest information is received from the terminal of the user via the input/output unit 100 (S101). Subsequently, the configuration design unit 200 automatically designs a specific system configuration that satisfies the system requirements (S102), generates information on the specific configuration and the design history, transmits the information to the control unit 301 together with the system requirements and the interest information received from the user, and requests document generation (S103). The interest information may include the interest component information illustrated in FIGS. 6A to 6D in addition to the interest information illustrated in FIG. 5. Alternatively, the interest component information that can be referred to from the interest information may be registered in the storage unit 400 in advance. The control unit 301 repeats the processing of S104 to S109 for each interest in the received interest information. For this purpose, first, it is confirmed whether all the interests have been processed (S104), and when there is an unprocessed interest (N in S104), the processing of S105 to S109 is sequentially executed for the unprocessed interest. Subsequently, the control unit 301 repeats the processing in S105 to S108 for each interest component in the target interest. For this purpose, first, it is confirmed whether all the interest components have been processed (S105), and when there is an unprocessed interest component (N in S105), the processing of S106 to S108 is sequentially executed for the unprocessed interest component. The specific content of the processing in S106 to S108 varies depending on the kind of the interest component, but basically, the extraction unit 303 extracts only the information of the type indicated for the target type included in the interest component information from the system requirement, the specific configuration, and the design history, and generates the post-extraction information (S106). Next, the conversion unit 304 converts the post-extraction information according to the instruction content based on the description of the conversion included in the interest component information to generate the post-conversion information (S107). Next, the shaping unit 305 shapes the post-conversion information according to the instruction content according to the description of shaping included in the interest component information to generate the post-shaping information (S108), and returns to S105. In a case where all the interest components have been processed (in the case of Y in S105), the control unit 301 merges the generation results by the interest components (S109), and adds the title of the chapter to generate the document by the target interest, and returns to S104. When all the interests have been processed (in the case of Y in S104), the control unit 301 merges the generation result of each interest (S110) and returns the merged document to the configuration design unit 200. Finally, the configuration design unit 200 returns the specific configuration of the design result and the document generation result by the document generation unit 300 to the user via the input/output unit 100 (S111).

### (Effect)

As described above, according to the first example embodiment, it is possible to design a specific system configuration that satisfies an input requirement, and generate and output a design document (for example, the document of FIG. 7) describing the system configuration. In particular, by dividing the existence of the system into a plurality of interests, it is possible to generate a design document that easily explains a complicated system.

### Second Example Embodiment

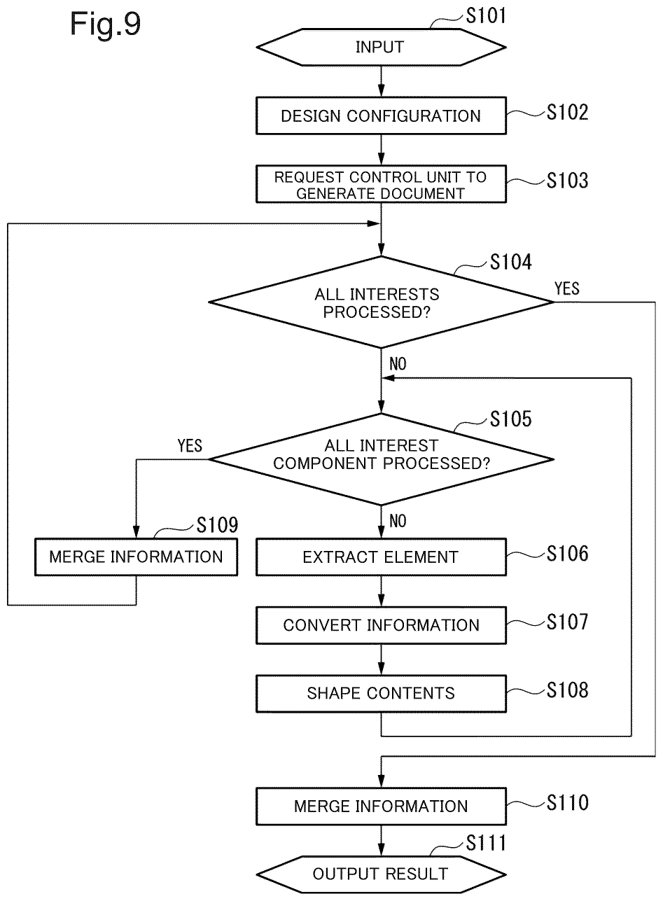

FIG. 10 is a block diagram illustrating an example of a functional configuration of an automatic design device according to a second example embodiment;

An automatic design device 800 includes an acceptance means 801, a design means 802, and a document generation means 803.

The acceptance means 801 receives an input of the interest information which is a definition of a requirement to be satisfied by the system and an interest in the system. The design means 802 generates a system configuration from the above requirements. The document generation means 803 extracts a part of the information from the requirement or the generated system configuration according to the extraction instruction included in the interest information, and generates the design document. The input/output unit 100 is an example of the acceptance means 801. The configuration design unit 200 is an example of the design means 802. The document generation unit 300 is an example of the document generation means 803.

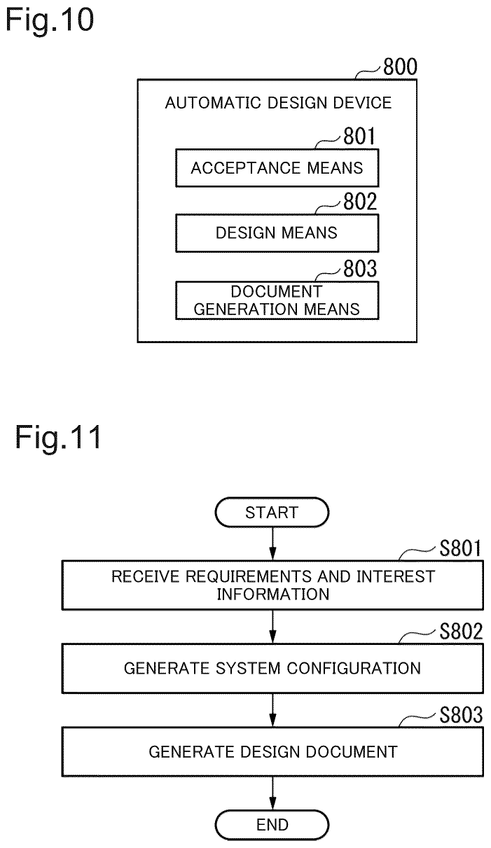

FIG. 11 is a flowchart illustrating an example of an operation of the automatic design device according to the second example embodiment.

The acceptance means 801 accepts an input of an interest information that is a definition of a requirement to be satisfied by a system and an interest in the system (S801), the design means 802 generates a system configuration from the requirement (S802), and the document generation means 803 extracts part of information from the requirement or the generated system configuration according to an extraction instruction included in the interest information, and generates a design document describing the system configuration (S803).

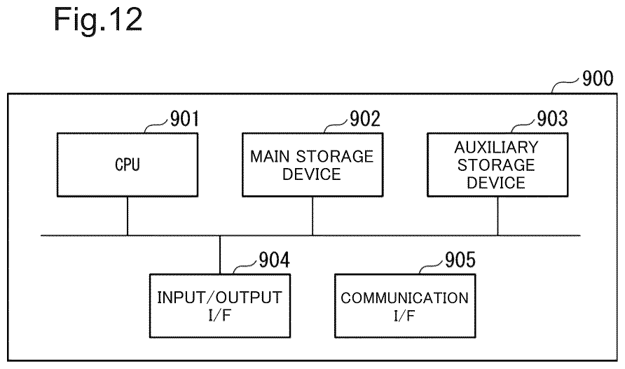

FIG. 12 is a diagram illustrating an example of a hardware configuration of the automatic design device according to each example embodiment.

A computer 900 includes a CPU 901, a main storage device 902, an auxiliary storage device 903, an input/output interface 904, and a communication interface 905. The automatic design devices 500 and 800 described above are implemented in the computer 900. Each function described above is stored in the auxiliary storage device 903 in the form of a program. The CPU 901 reads the program from the auxiliary storage device 903, expands the program in the main storage device 902, and executes the above processing according to the program. The CPU 901 secures a storage area in the main storage device 902 according to the program. The CPU 901 secures a storage area for storing data being processed in the auxiliary storage device 903 according to the program.

A program for implementing all or part of the functions of the automatic design devices 500 and 800 may be recorded in a computer-readable recording medium, and the processing of each functional unit may be performed by causing a computer system to read and execute the program recorded in the recording medium.

The “computer system” here includes hardware such as an OS and peripheral devices. The “computer system” is assumed to include a home page provision environment (or display environment) when the WWW system is used. The “computer-readable recording medium” refers to a portable medium such as a CD, a DVD, or a USB, or a storage device such as a hard disk built in a computer system. In a case where this program is distributed to the computer 900 via a communication line, the computer 900 that has received the distribution may expand the program in the main storage device 902 and execute the above processing. The program may be for achieving a part of the functions described above, and the functions described above may be achieved in combination with a program already recorded in the computer system.

Although one example embodiment of the present disclosure has been described in detail with reference to the drawings, the specific configuration is not limited to the above, and various design changes and the like can be made without departing from the gist of the present invention. One aspect of the present disclosure can be variously modified within the scope indicated in the claims, and example embodiments obtained by appropriately combining the technical means disclosed in the different example embodiments are also included in the technical scope of the present disclosure. A configuration in which the elements that are described in each of the above example embodiments and modifications and that have similar effects are replaced with each other is also included. And each embodiment can be appropriately combined with other embodiments.

Some or all of the above example embodiments may be described as the following Supplementary Notes, but are not limited to the following.

### (Supplementary Note 1)

An automatic design device including: a means for receiving an input of interest information that is a definition of a requirement to be satisfied by a system and an interest in a system; a means for generating a system configuration from the requirements; and a means for generating a design document for describing the system configuration in accordance with the interest information, in which the means for generating the design document extracts part of information from the requirement or the generated system configuration according to an extraction instruction included in the interest information to generate the design document.

### (Supplementary Note 2)

The automatic design device according to Supplementary Note 1, in which the means for generating the system configuration further outputs design history information that is information of a design process of generating the system configuration from the requirement in addition to the system configuration, and the means for generating the design document generates the design document including determination on which a specific element constituting the system configuration is selected, another option in the determination, and a selection reason in the determination from the design history information.

(Supplementary Note 3) The automatic design device according to Supplementary Note 2, in which the means for generating the system configuration further generates information regarding a selectivity of each of a plurality of options in each determination in the design process, and the means for generating the design document limits the design reason to be generated to determination with a low selectivity.
(Supplementary Note 4) The automatic design device according to Supplementary Notes 1 to 3, in which the means for generating the design document uses, as a selection reason of the determination in the design process, superiority or inferiority based on a satisfaction status of a constraint condition and an optimum condition of an option in the determination.
(Supplementary Note 5) The automatic design device according to Supplementary Notes 1 to 4, in which the receiving means receives an input of the interest information including a plurality of the interests, and the means for generating the design document is configured to generate a part of the design document relevant to each of the plurality of the interests; and configure the design document further including the part of the design document.

### (Supplementary Note 6)

The automatic design device according to Supplementary Notes 1to 5, in which the means for generating the design document generates the design document by extracting and converting part of information from the generated system configuration according to the extraction instruction and a conversion instruction included in the interest information.

(Supplementary Note 7) The automatic design device according to Supplementary Notes 1to 6, in which the means for generating the design document shapes the part of information extracted from the requirement or the generated system configuration into any format of a sentence, a drawing, a list, or a table.

### (Supplementary Note 8)

An automatic design method executed by a computer, including: receiving an input of interest information that is a definition of a requirement to be satisfied by a system and an interest in a system; generating a system configuration from the requirements; and extracting part of information from the requirement or the generated system configuration in accordance with an extraction instruction included in the interest information to generate a design document for describing the system configuration.

### (Supplementary Note 9)

A program for causing a computer to function as: a means for receiving an input of interest information that is a definition of a requirement to be satisfied by a system and an interest in a system; a means for generating a system configuration from the requirements; and a means for extracting part of information from the requirement or the generated system configuration in accordance with an extraction instruction included in the interest information to generate a design document for describing the system configuration.

1. An automatic design device comprising:
at least one memory that is configured to store instructions; and
at least one processor that is configured to execute the instructions to:
receive an input of interest information that is a definition of a requirement to be satisfied by a system and an interest in a system;
generate a system configuration from the requirement; and
generate a design document for describing the system configuration in accordance with the interest information, wherein
the generating the design document includes extracting part of information from the requirement or the generated system configuration according to an extraction instruction included in the interest information to generate the design document.

2. The automatic design device according to claim 1, wherein
generating the system configuration further includes generating design history information that is information of a design process of generating the system configuration from the requirement in addition to the system configuration, and
the generating the design document includes generating the design document including determination on which a specific element included in the system configuration is selected, another option in the determination, and a selection reason in the determination from the design history information.

3. The automatic design device according to claim 2, wherein
the generating the system configuration further includes generating information regarding a selectivity of each of a plurality of options in each determination in the design process, and
the generating the design document includes limiting the selection reason to be generated to determination with a low selectivity.

4. The automatic design device according to claim 2, wherein
the generating the design document includes using, as a selection reason in the determination in the design process, superiority or inferiority based on a satisfaction status of a constraint condition and an optimum condition of an option in the determination.

5. The automatic design device according to claim 1, wherein
receiving the input of interest information includes receiving an input of the interest information including a plurality of the interests, and
the generating the design document is configured to:
generate a part of the design document relevant to each of a plurality of the interests; and
configure the design document further including the part of the design document.

6. The automatic design device according to claim 1, wherein
the generating the design document generates the design document by extracting and converting part of information from the generated system configuration according to the extraction instruction and a conversion instruction included in the interest information.

7. The automatic design device according to claim 1, wherein
the generating the design document shapes the part of information extracted from the requirement or the generated system configuration into any format of a sentence, a drawing, a list, or a table.

8. An automatic design method executed by a computer, comprising:
receiving an input of interest information that is a definition of a requirement to be satisfied by a system and an interest in a system;
generating a system configuration from the requirement; and
extracting part of information from the requirement or the generated system configuration in accordance with an extraction instruction included in the interest information to generate a design document for describing the system configuration.

9. A tangible and non-transitory program for causing a computer to:
receive an input of interest information that is a definition of a requirement to be satisfied by a system and an interest in a system;
generate a system configuration from the requirement; and
extract part of information from the requirement or the generated system configuration in accordance with an extraction instruction included in the interest information to generate a design document for describing the system configuration.
